(19) United States
(12) Patent Application Publication
(10) Pub. No.: US 2024/0354522 A1
(43) Pub. Date: Oct. 24, 2024

(54) NON-VOLATILE NANOMAGNETIC MATRIX MULTIPLIER-ACCUMULATOR

(71) Applicant: VIRGINIA COMMONWEALTH UNIVERSITY, Richmond, VA (US)

(72) Inventor: Supriyo BANDYOPADHYAY, Glen Allen, VA (US)

(21) Appl. No.: 18/682,538

(22) PCT Filed: Sep. 20, 2022
(86) PCT No.: PCT/US2022/076727

§ 371 Date: Feb. 9, 2024

Related U.S. Application Data
(60) Provisional application No. 63/261,382, filed on Sep. 20, 2021.

(51) Int. Cl. G06G 7/16; G11C 11/16; H10B 61/00; H10N 50/10

(52) U.S. Cl. CPC G06G 7/16; G11C 11/161; G11C 11/1675; H10B 61/00; H10N 50/10

(57) ABSTRACT

Provided herein is a magnetic tunnel junction (MTJ) based non-volatile non-binary matrix multiplier comprising a straintronic MTJ “multiplier” and a spin-orbit torque driven MTJ “accumulator”. The multiplier quantity (one element of one matrix) and the multiplicand quantity (one element of the other matrix) are encoded in voltage pulses that are applied across two different sets of the straintronic MTJ terminals to produce a MTJ current output that is proportional to the product of the multiplier and multiplicand.

### CROSS REFERENCE TO RELATED APPLICATIONS

This application claims the benefit under 35 U.S.C. § 119 (e) of U.S. Provisional Patent Application No. 63/261,382, filed Sep. 20, 2021, which is hereby incorporated by reference in its entirety.

### STATEMENT REGARDING FEDERALLY SPONSORED RESEARCH OR DEVELOPMENT

This invention was made with Government Support under Grant Nos. CCF-2001255 and CCF-2006843 awarded by the National Science Foundation. The Government has certain rights in the invention.

### TECHNICAL FIELD

Embodiments generally relate to systems and devices for analog computation, machine learning and artificial intelligence, and, more particularly, to systems and devices directed to utilizing one or more magnetic tunnel junctions (MTJ) and to multiplications of non-binary matrices.

### BACKGROUND

Artificial intelligence (AI) has a wide range of applications in modern life (smart cities, smart appliances, autonomous self-driving vehicles, information processing, speech recognition, patent monitoring, etc.). AI can leverage machine learning to perform two primary functions—training and inference. Machine learning in the context of neural networks is generally referred to as “deep learning.” Algorithms for these tasks require multiplication of large matrices, such as in updating the synaptic weight matrices in deep learning networks, which is an essential feature of training a neuronal circuit.

There are current devices, referred to as “hardware accelerators” directed to performing matrix multiplications. However, these have shortcomings. One is data volatility, i.e., when the hardware accelerator is powered down all computational results within the accelerator are lost. Another is high power consumption. Another is large footprint. Optical matrix multipliers have low energy consumption, but large footprint and electronic matrix multipliers have small footprint, but high energy consumption.

Accordingly, what is needed is a non-volatile, low power consumption, small footprint hardware accelerator for matrix multiplication. Magnetic matrix multipliers can satisfy this need; however, magnetic multipliers that are currently extant are binary in nature, i.e. they can multiply only matrices whose elements are either 0 or 1 and cannot multiply non-binary matrices whose elements are different from 0 or 1. This is inadequate for most artificial intelligence and machine learning tasks. The current invention is a non-binary magnetic matrix multiplier that can multiply any two matrices, not just binary ones, which makes it much more powerful than a currently existing magnetic matrix multiplier.

### SUMMARY

A matrix multiplier has two components: a multiplier and an accumulator. In an embodiment a non-volatile MTJ based accumulator is provided, which can include a spin torque generating conducting body and, non-conductively secured to or against an external surface of the spin torque generating conducting body, a hard-layer-soft layer MTJ, where the soft layer acts as a domain wall synapse.

An embodiment of a non-volatile multiplier is also provided which includes a straintronic MTJ whose conductance can be changed by straining the soft layer of the MTJ with a gate voltage applied to a piezoelectric substrate upon which the MTJ is fabricated. A magnetic field may be applied in the plane of the soft layer to ensure that the MTJ conductance versus the gate voltage characteristic has a linear region. The MTJ is biased in that linear region with a de voltage source to make it act as a multiplier. The multiplier and the multiplicand are encoded in the gate voltage and another voltage applied across the MTJ. The current that flows through the MTJ (and any resistor connected in series with it) is proportional to the product of the multiplier and the multiplicand. This current is passed through the spin torque generating conducting body of the accumulator to combine the multiplier with the accumulator and implement the matrix multiplier.

This Summary identifies example features and aspects and is not an exclusive or exhaustive description of disclosed subject matter. Whether features or aspects are included in or omitted from this Summary is not intended as indicative of relative importance of such features or aspects. Additional features are described, explicitly and implicitly, as will be understood by persons of skill in the pertinent arts upon reading the following detailed description and viewing the drawings. which form a part thereof.

### BRIEF DESCRIPTION OF THE DRAWINGS

FIG. 1 shows a circuit schematic of an example non-volatile spin orbit torque (SOT) coupled nanomagnetic magnetic tunnel junction based matrix multiplier according to one or more embodiments.

FIG. 2 shows a graphics labeled, three-dimensional (3D) view of structural features of an example SOT coupled perpendicular MTJ (p-MTJ) accumulator mounted on an example heavy metal (HM) strip configured SOT coupling generator, for various configurations of non-volatile spin orbit torque coupled nanomagnetic magnetic tunnel junction based matrix multipliers according to one or more embodiments.

FIG. 3A shows a graphics model of a first state, and FIG. 3B shows the graphics model of a second state, in a progressing domain wall movement in a p-MTJ FM soft layer, corresponding to current flow through the HM strip configured SOT coupling generator, in non-volatile spin orbit torque coupled nanomagnetic magnetic tunnel junction based multiplication-accumulation according to one or more embodiments.

FIG. 4 shows a graphic representation of a parallel three conductance model of magnetization-state-dependent conductance of a p-MTJ for a SOT coupled accumulator for various configurations of non-volatile spin orbit torque coupled nanomagnetic magnetic tunnel junction based matrix multiplier according to one or more embodiments.

FIG. 5 shows a graphics labeled, 3D view of structural features of an alternative ellipsoid accumulator p-MTJ mounted on the FIG. 2 example HM strip SOT generator for a non-volatile spin orbit torque coupled nanomagnetic magnetic tunnel junction based matrix multiplier according to one or more embodiments.

FIG. 6 shows a hybrid graphic representing, via circuit schematic overlay of a three-dimensional view of an example structural configuration, an MTJ straintronic configured non-volatile spin orbit torque coupled nanomagnetic magnetic tunnel junction based matrix multiplier according to one or more embodiments.

FIG. 7 shows an example geometry and certain dimension parameters of an elliptical soft layer of a straintronic MTJ

FIG. 8 shows an example z-axis designation along the major, or easy axis of the soft layer and y-axis along the minor, or hard axis, an example pointing direction of the +z direction, and a corresponding polar angle. It shows a plot of an example steady state angle between an example multiplier MTJ FM hard layer and FM soft layer as a function of gate voltage.

FIG. 9 shows a plot of an example steady state angle between an example multiplier MTJ FM hard layer and FM soft layer as a function of gate voltage.

FIG. 10 shows a plot of an example multiplier MTJ conductance versus gate voltage.

FIG. 11 shows a logic flow diagram of operations in an example matrix multiplication process provided on a non-volatile spin orbit torque coupled nanomagnetic magnetic tunnel junction based matrix multiplier according to one or more embodiments.

### DETAILED DESCRIPTION

Example embodiments include a straintronic MTJ based non-volatile multiplier-non-volatile MTJ-based accumulator that can provide, among other features and advantages, reliable non-volatile non-binary multiplication of matrices and other sum-of-products processing at low energy and low hardware footprint cost. Example applications can include, but are not limited to, artificial intelligence (AI) and other applications that can require high speed multiplication of row-column matrices.

According to various embodiments a non-volatile multiplier-accumulator can include a straintronic MTJ based multiplier that is spin orbit torque (SOT) coupled to a magnetic tunnel junction (MTJ) based accumulator. The multiplier and multiplicand are encoded in voltage pulses provided as inputs to the multiplier and the output of the multiplier is a current pulse whose magnitude is proportional to the product of the multiplier and multiplicand. In an embodiment the accumulator can comprise a heavy metal (HM) strip, and can be configured to receive the output current pulses from the multiplier and, in response, effectuate generation by the HM strip of a spin orbit torque (SOT) pulse that can move the domain wall in the soft layer of the accumulator MTJ by a distance proportional to the current injected into it and hence proportional to the product of the multiplier voltage and the multiplicand voltage. Successive current pulses, cach proportional to the product of an element along the row of the first matrix and an element along the column of the second matrix, move the domain wall by an amount proportional to the product and these domain wall displacements add up (or accumulate) to produce a total displacement that is proportional to the sum of the products of the row elements and column elements, thereby producing one element of the product matrix. According to various embodiments, the MTJ based accumulator can comprise an accumulator MTJ that includes a hard ferromagnetic (FM) layer and a FM soft layer, non-conductively supported on the HM strip in an arrangement that produces, corresponding to the SOT pulse, a SOT coupling between the HM strip and the MTJ's FM soft layer. In the various embodiments, the arrangement of the FM soft layer and configuration of the HM strip can combine such that, within a defined range of multiplier voltages and multiplicand voltages, the corresponding SOT coupling with the FM soft layer deterministically effects a change in the non-volatile magnetization state proportional to the SOT pulse. The change is therefore proportional to the product of the multiplier voltage and the multiplicand voltage.

According to various embodiments, the multiplier providing this SOT generation function can include features that in combination, effectuate flow of a multiplication result current pulse through the HM strip that is both proportional to the multiplication of the product of the multiplier voltage and the multiplicand voltage, and has a current density through the HM strip within a density range in which the HM strip produces a SOT coupling with FM soft layer that obtains a deterministic change in the magnetization that is proportional to the SOT coupling, i.e., proportional to the multiplication product. According to various embodiments the current path can include a voltage controlled conductance which can be controlled by the multiplicand voltage pulse, e.g., via a multiplicand terminal. The above configuration can effectuate, through the voltage controlled current path and its HM strip, in response to concurrent reception at the multiplier terminal and the multiplicand terminal of, respectively, the multiplier voltage pulse and the multiplicand voltage pulse, a current through the HM strip proportional to the product of the multiplier voltage and the multiplicand voltage.

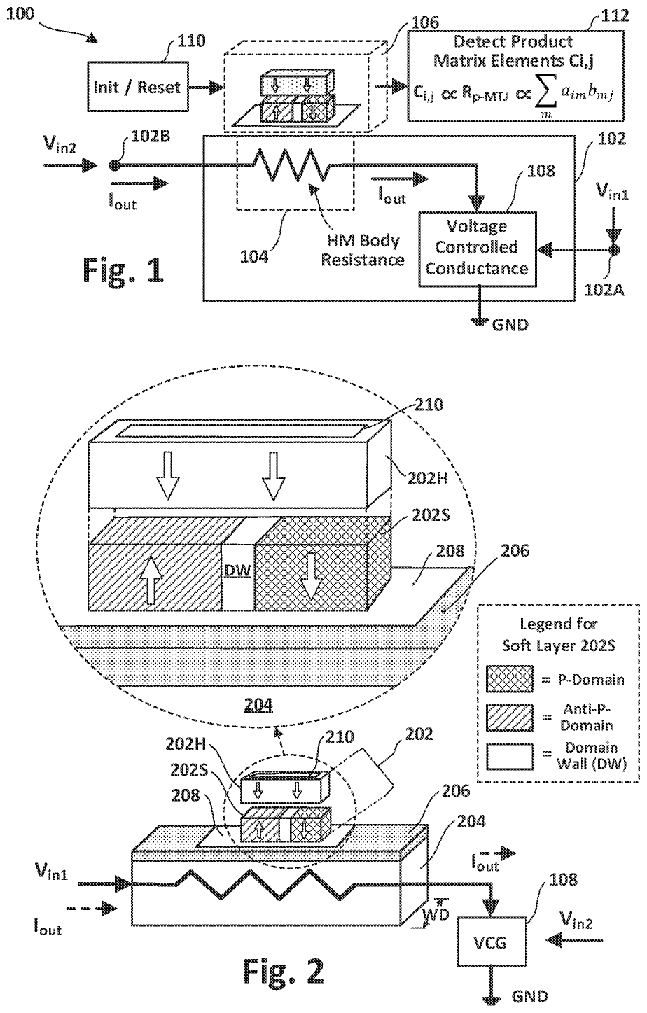

FIG. 1 shows a circuit schematic of an example non-volatile spin orbit torque coupled nanomagnetic magnetic tunnel junction based matrix multiplier 100 (hereinafter alternatively recited “NVM, SOT coupled MTJ based MXP 100”) according to one or more embodiments. It will be understood that “NVM, SOT coupled MTJ based MXP,” as used herein, is an arbitrary coined alternative recitation of the word sequence “non-volatile spin orbit torque coupled nanomagnetic magnetic tunnel junction based matrix multiplier” having no intrinsic meaning.

The FIG. 1 configuration of the NVM, SOT coupled MTJ based MXP 100 can include a multiplier 102, comprising a heavy metal (HM) conductor body 104 and configured to receive, e.g., at a first operand port 102A, a first operand voltage pulse Vin1 and, at a second operand port 102B, a second operand voltage pulse Vin2. As described in more detail in later paragraphs, the first operand voltage pulses Vin1 and second operand voltage pulses Vin2, according to various embodiments, may be configured with a common pulse width, which will be referenced herein as “Δt.” Contemplated applications and environments in which NVM, SOT coupled MTJ based MXP devices according to one or embodiments, such as the FIG. 1 example NVM, SOT coupled MTJ based MXP 100, and various adaptations and modification thereof may be used, can provide the first operand voltage pulses Vin1 and second operand voltage pulses Vin2 in the Δt pulse width form, or can include pulse-generator or pulse width converter circuitry, or both.

Referring to FIG. 1, the NVM, SOT coupled MTJ based MXP 100 according to various embodiments can further comprise a non-volatile SOT coupled MTJ accumulator 106. The non-volatile SOT coupled MTJ accumulator 106 can include an MTJ, graphically represented in the figure as comprising a ferromagnetic (FM) soft layer, and spaced above the FM soft layer an FM hard layer. According to various embodiments, the FM soft layer can be arranged proximal to, e.g., in a non-conductive contact against the HM conductor body 104. In one or more embodiments, the FM hard layer can be configured with a fixed magnetic anisotropy, and the FM soft layer can be configured to be deterministically magnetizable, by application of a magnitude of SOT coupling that can be effectively generated by practicable implementations of the HM conductor body 104 and related features of the multiplier 102 thar are described in more detail in subsequent paragraphs. As used in this description, in the context of an FM hard layer of an MTJ, such as the FM hard layer of the non-volatile SOT coupled MTJ accumulator 106, fixed magnetic anisotropy” means not unacceptably susceptible to unintended material loss of magnetic anisotropy due to normal operational exposure, e.g., exposure to normal environmental noise, and to SOT coupling operationally applied to deterministically change magnetization state of a corresponding FM soft layer.

According to various embodiments, input-output functionality of the multiplier 102 can include effectuating, responsive to concurrently receiving a first operand voltage pulse Vin1 at the first operand input terminal 102A and a second operand voltage pulse Vin2 at the second operand input terminal, a pulse of a SOT coupling pulse between the HM conductor body 104 and the FM soft layer of the non-volatile SOT coupled MTJ accumulator 106. In further accordance with various embodiments, such functionality of the multiplier 102 can also include effectuating the magnitude of the above described pulse of SOT coupling to be, conjunctively: i) proportional to a multiplication product of the second operand voltage pulse Vin2 and the first operand voltage pulse Vin1, and ii) be generated with temporal-spatial characteristics, including magnitude of the coupling at the FM soft layer, that deterministically produces a corresponding change in the magnetization of the FM soft layer.

According to various embodiments, features of the multiplier 102, the HM conductor body 104, and the FM soft layer of the non-volatile SOT coupled MTJ accumulator 106, in providing the above-described multiplication product dependent changes in FM soft layer magnetization can include instantiation, in the FM soft layer when in an initialized fully parallel magnetic anisotropic state, of an anti-parallel domain, having an area deterministically proportional to the magnitude of the SOT coupling. In such embodiments, features can also include subsequent successive enlargements of the instantiated non-parallel domain, each enlargement being proportional to a magnitude of a corresponding SOT coupling, i.e., proportional to a multiplication product of a column element of given row in a first matrix A by a row element of a corresponding column in a second matrix B. In one or more embodiments, instantiation of the antiparallel domain can include establishing a domain wall between said domain and the remaining area of the FM soft layer. In such embodiments, the instantiation effectively creates an anti-parallel and a parallel domain, separated by a domain wall.

Regarding examples of first operand voltage pulses Vin1 and second operand voltage pulses Vin2, in a matrix multiplication processes, e.g., multiplying a first matrix A by a second matrix B, first operand voltage pulses Vin1 and second operand voltage pulses Vin2 may be provided to the NVM, SOT coupled MTJ based MXP 100 as a series of blocks, Continuing with the example, cach of the blocks can correspond to a particular row of the matrix A, and a particular column of the matrix B, and in such an example, each of the blocks can comprise a sequence of integer R operand pairs, each pair having another column element of the particular row of matrix A and another row element of the particular column of matrix B. By operation described in more detail in subsequent paragraphs, the multiplier 102 can perform, responsive to each of the integer R operand pairs, a multiplication using the first element in the pair as a multiplier and the second clement as a multiplicand

In the FIG. 1 configuration, such functionality is provided by a voltage controlled conductance 108 that, in series with the HM conductor body 104, provides a voltage controlled path from the multiplier terminal 102B to the local current sink, labelled “GND.” The configuration further includes the voltage controlled conductance 108 being controlled, e.g., via the multiplicand terminal 102A, by the multiplicand voltage. This configuration provides, responsive to concurrent reception of the multiplier voltage pulse as Vin2 and multiplicand voltage pulse as Vin1, a current Iout from the multiplier terminal 102B through the HM conductor body 104 to GND that is proportional to Vin2, the multiplier voltage, divided by the sum of the resistance of the HM conductor body 104 and the resistance through the voltage controlled conductance 108. As described in more detail in later paragraphs, resistance through the HM conductor body 104 can be much less than the resistance through the voltage controlled conductance 108. As also described later in more detail, effects of the HM conductor body 104 resistance and other factors can be readily removed, e.g., by a straightforward, one-time, calibration process. Accordingly, the configuration shown in FIG. 1 can provide Iout2, which passes through the HM conductor body 104, as proportional to the multiplication product of the multiplier voltage and the multiplicand voltage.

According to various embodiments, the NVM, SOT coupled MTJ based MXP 100 can further include an initialization/reset logic block 110 that can be configured to selectively reset. e.g., to a fully parallel magnetization state, the FM soft layer of the non-volatile SOT coupled MTJ accumulator 106. In an illustrative example, of multiplying two K×K row-column matrices, a process can include K² repeats of feeding K operand pairs, cach being another column element from a row of the first matrix and a corresponding row clement from a column of the second matrix. Responsive to each of the K operand pairs, the magnetization state of the FM soft layer of the non-volatile SOT coupled MTJ is changes by an amount proportional to the multiplication product. After the K multiplications, the conductance of the FM soft layer is detected, which indicated the sum of the multiplication products and, hence, the value of another element of the product matrix. The initialization/reset logic block 110 then re-initializes or resets the magnetization state of the FM soft layer, e.g., to a fully parallel state, aligned with the FM hard layer. The process then repeats, using another row of the first matrix or another column or the second matrix, or both.

As described above, after performing the K multiplications, e.g., a row by a column, a resource can read the resulting conductance of the non-volatile SOT coupled MTJ accumulator 106. Implementation can comprise a Detect Product Matrix Elements Ci,j block 112 to perform this function.

FIG. 2 shows a graphics labeled, three-dimensional (3D) view of structural features of an example perpendicular MTJ (p-MTJ) accumulator 202 mounted on an example heavy metal (HM) strip configured HM conductor body 204, for various configurations of non-volatile spin orbit torque coupled nanomagnetic magnetic tunnel junction based matrix multipliers according to one or more embodiments. The p-MTJ accumulator 202 comprises a FM soft layer 202S and, spaced above layer 202, an FM hard layer 202H. The HM strip configured HM conductor body will be alternatively referenced for purposes of description as “HM strip SOT coupler 204.” The non-conducting support arrangement for the p-MTJ accumulator 202 comprises an insulating layer 206 positioned, e.g., disposed on, on an upper surface of the HM strip SOT coupler 204. For purposed of detecting the conductance, and hence magnetization state, of the p-MTJ accumulator 202, a lower metal film 208 is arranged to contact a lower surface of the FM soft layer 202, and an upper metal film 210 can be arranged on an upper surface

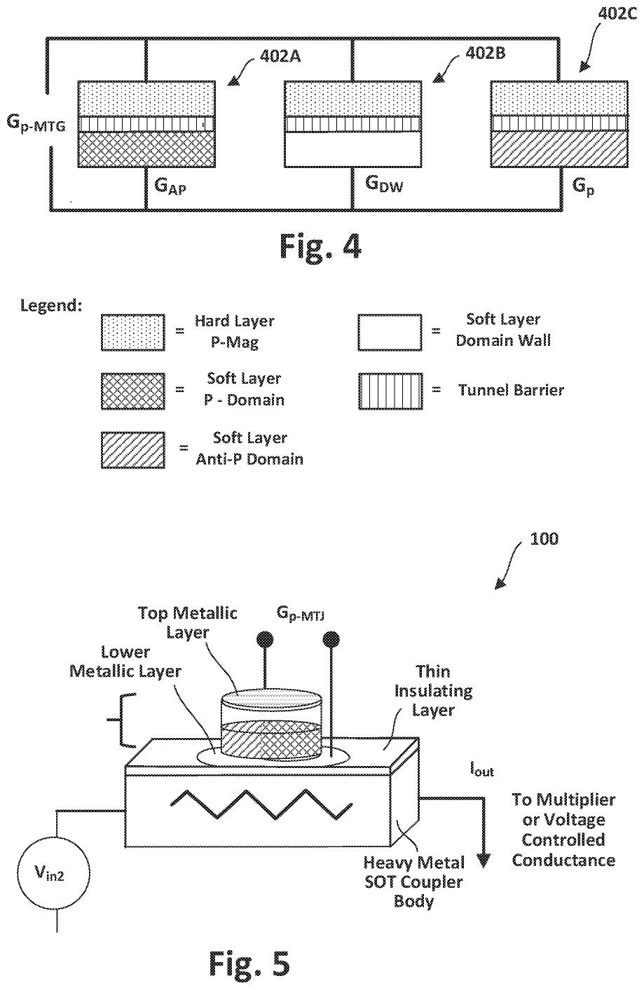

The FM soft layer 202S is shown in example magnetization state comprising a p-domain, an anti-p domain, and a domain wall, each respectively labeled by cross-hatching according to the cross-hatching legend on the figure. As described above in reference to the FIG. 1 detect product matrix clement block 112, and as further described in more detail later in this disclosure, for example in reference to FIG. 4, a conductance of the p-MTJ structure of the p-MTJ accumulator 202 can vary in a linear relation to the respective areas of the p-domain, anti-p domain, and domain wall. For measurement of the conductance, and corresponding detection of matric elements of the product matrix, a conducting terminal or trace can connect from the first metal layer 208 to a first measurement point and another conducting terminal or trace can connect from the second metal layer 210 to a second measurement point. A conductance measurement resource, as described in reference to the FIG. 1 detect product matrix element block 112, can therefore be configured to connect, for example to the first and second measurement points.

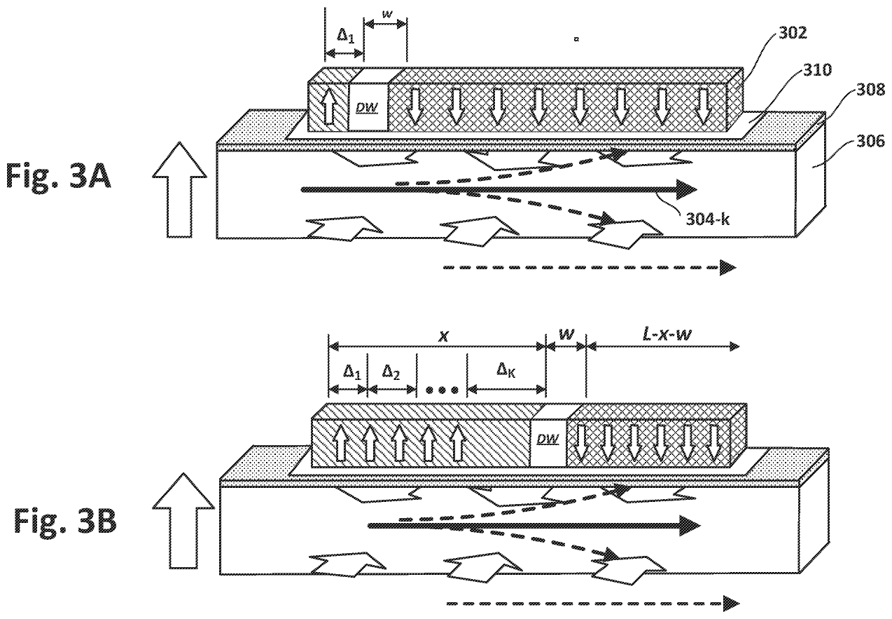

FIG. 3A shows a graphics model of a first magnetization state, and FIG. 3B shows the graphics model of a K-th magnetization state produced by a progressing domain wall DW movement in a p-MTJ FM soft layer 302, produced,, for example, by passing a succession of integer K current pulses, generically represented by arrow Iout-k, through an example HM strip configured SOT coupler 304 on which the p-MTJ FM soft layer 302 is non-conductively supported. The FIG. 3A-3B model shows the non-conductive support comprising an insulating layer 306, and also shows an example lower metal layer 308 for measurement of conductance, as is described in more detail above and further described in reference to FIG. 4.

Each of the current pulses Iout-k passes through the HM strip configured SOT coupler 304 and, because of spin-orbit interactions in the structure 304 heavy metal material, a spin orbit torque (SOT) is generated. The SOT can extend out from the surface of the HM strip configured SOT coupler 304 supporting the MTJ accumulator 302, through the thin insulating layer 306, through the metal layer 308 and into the FM soft layer 302. The SOT then injects spins into the FM soft layer 302, causing domain wall motion due to the spin Hall effect. . . . The velocity of the domain wall movement can be proportional to the current density through the HM strip configured SOT coupler 306, i.e., the magnitude of the current pulse Iout-k divided by the cross-sectional area of the body 306. As described above, in accordance with various embodiments, the duration of each current pulse Iout. Therefore, the distance of domain wall movement effectuated by each Iout-k can be proportional the amplitude of the Iout-k pulse.

After a number of Iout-k pulses a fraction of the soft layer will have magnetization parallel to that of the hard layer, a small fraction will be un-magnetized and will serve as a boundary or “domain wall” between the parallel magnetized portion and the remainder, which magnetization anti-parallel to that of the FM hard layer, which is not explicitly visible in FIGS. 3A-3B. antiparallel magnetization. The relation of the fractions of the FM soft layer 302 with parallel and anti-parallel magnetization changes with each successive Iout-k current pulse flowing through the HM strip configured SOT coupler 304. Upon receiving integer K Iout-k pulses, the resulting p-MTJ magnetization state can uniquely indicate the sum of the spin torque pulses, i.e., the sum of the K multiplication products.

Conductance of the p-MTJ, measured between the FM hard layer and the FM soft layer is a combination of three parallel conductances, one being the conductance of the parallel domain region, another being the conductance of the anti-parallel domain, and the third being the conductance of the domain wall DW.

FIG. 4 shows a graphic representation of a parallel three conductance model of magnetization-state-dependent conductance, G_{p-MTJ} (x) of a p-MTJ of a SOT coupled accumulator, such as the FIG. 2 example 202, in various example non-volatile spin orbit torque coupled nanomagnetic magnetic tunnel junction based matrix multipliers according to one or more embodiments.

The Gp-MTJ (x) conductance can be represented by the following Equation (1)

$${G}_{p - MTJ} ( x ) = \frac{w}{L} {G}_{DW} + {G}_{p} ( 1 - \frac{w}{L} ) - \frac{( {G}_{p} - {G}_{AP} )}{L} x \qquad Equation ( 1 )$$

where
x is the distance from one of the opposing ends of the soft layer,
L is the length of the soft layer, excluding the domain wall width DW,
Gₚ is the p-MTJ conductance in the parallel state G_{AP} is the conductance in the anti-parallel state, and Gpw is the conductance associated with the domain wall in the soft layer.

FIG. 5 shows a graphics labeled, 3D view of structural features of an alternative ellipsoid accumulator p-MTJ mounted on the FIG. 2 example HM strip SOT generator for a non-volatile spin orbit torque coupled nanomagnetic magnetic tunnel junction based matrix multiplier according to one or more embodiments.

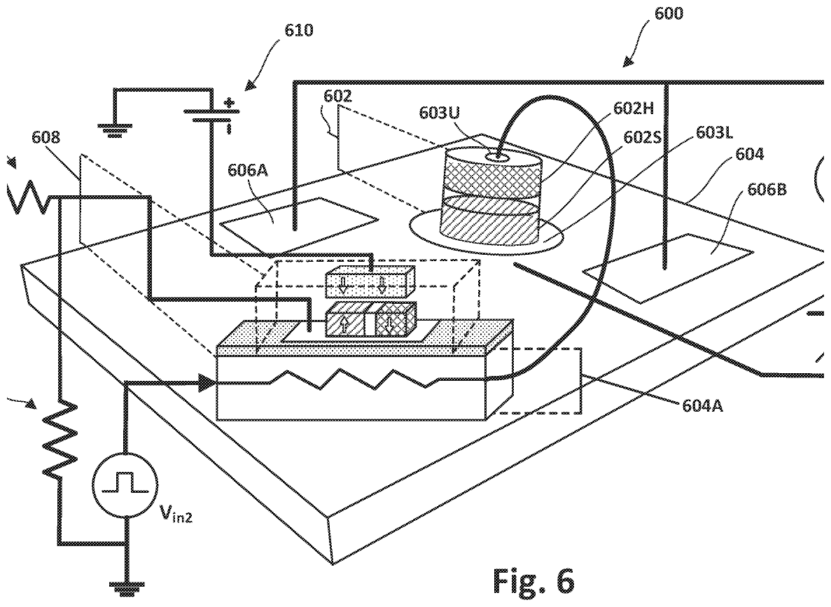

FIG. 6 shows a hybrid graphic representing, via circuit schematic overlay of a three-dimensional view of an example structural configuration, an MTJ straintronic configured non-volatile NMG, SOT coupled MTJ matrix multiplier 600 according to one or more embodiments.

The MTJ straintronic configured non-volatile NMG, SOT coupled MTJ matrix multiplier 600 according to one or more embodiment can include an elliptical MTJ 602 having an elliptical hard layer 602H and elliptical soft layer 602S, separated by an intervening insulating spacer layer. It will be understood that as used herein, in this context, “hard” and “soft” mean hard magnetically and soft magnetically. The elliptical soft layer 602S can be magnetostrictive and placed in an elastic contact with an underlying poled piezoelectric thin film 604 that can be deposited on a conducting substrate. Such construction can constitute a 2-phase multiferroic. Two electrically shorted electrodes, 606A and 606B, (collectively “electrically shorted electrode pair 606A-606B”) on the piezoelectric thin film 604 can be arranged to flank the elliptical MTJ 602, and the back of the substrate can be connected to ground.

In an operation, a (gate) voltage VG applied to the electrically shorted electrode pair 606A-6066B, can generate biaxial strain in the piezoelectric thin film 604. The biaxial strain can transfer to the elliptical soft layer 602S. The strain can be either compressive along the major axis and tensile along the minor axis, or vice versa, depending on the voltage polarity. These biaxial strains can rotate the elliptical soft layer 602S magnetization by an angle via the Villari effect, while the elliptical hard layer 602H magnetization can remain unaffected. The resistance of the elliptical MTJ 602 depends on the angle between the magnetizations of the hard layer 602H and soft layer 602S. Therefore the biaxial strain induced by the gate voltage V_{G} changes the elliptical MTJ 602 resistance.

In an implementation of functionality of the multiplier, a constant current source I_{bias} is connected between the hard and soft layers (terminals ‘1’ and ‘2’), as shown in FIG. 1 (a). This drives a current through the MTJ. The gate voltage VG is applied at terminal 3 and a fourth terminal is connected to the hard layer, which outputs a voltage V₀. Terminal 2 is grounded and hence V₀=R_{MTJ}I_{bias}, where R_{MTJ} is the resistance of the MTJ that can be altered by the gate voltage V_{G}, as explained before.

For practices, determination of a respective ranges of the multiplier voltages and multiplicand voltage at the straintronic MTJ can be obtained via modeling rotation □ of the soft layer's magnetization as a function of the gate voltage V_{G} in the presence of thermal noise. Such modeling can use, for example, stochastic Landau-Lifshitz-Gilbert simulations. MTJ resistance through the straintronic MTJ can be according to Equation (2)

$${R}_{MTJ} = {R}_{P} + \frac{{R}_{AP} - {R}_{P}}{2} [ 1 - cos θ ] \qquad Equation ( 2 )$$

where,
R_{P} is the MTJ resistance when the magnetizations of the hard and soft layers are mutually parallel and

R_{AP} is the MTJ resistance when the magnetizations are antiparallel.

From the θ_{SS} versus V_{G} relation, the R_{MTJ} versus V_{G} characteristic can be calculated. With appropriate proper choice of MTJ parameters, a region can be found in which

$${R}_{MTJ} ∝ \frac{1}{( {V}_{G} - δ )} ,$$

i.e., the transfer characteristic V₀ versus V_{G} is roughly hyperbolic can be identified. When V_{G} is chosen in such a region, one can perform an analog multiplication of two voltages Vᵢₙ₁ and Vᵢₙ₂ with a single s-MTJ by using a (variable) voltage source δ.

### EXAMPLE 1

Referring to FIG. 2, a non-limiting example HM strip 202 will assumed as formed of platinum (Pt) and configured with a width WD of, e.g., 500 nm, a thickness TH of 5 nm, and length LT of 1 μm. An example energy dissipation, referred to as “EXD” for purposes of description, associated with domain wall DW can be, for example, approximately as defined in Equation (3),

$$EXD = {I}^{2} R Δ t \qquad Equation ( 3 )$$

where I is the current inducing the domain wall motion, R is the resistance of the HM strip 202 and Δr is the pulse width. Since the example HM strip 202 is assumed having a width of 500 nm, thickness 5 nm, the example cross-sectional area is 2500 nm². A non-limiting example current density through the HM strip 202 that, subject to an appropriate configuration of the insulating layer 208 and metal conducting layer 210 configuration, can induce domain wall motion in the MTJ FM soft layer 206S can be equal or approximately equal on the order of 10¹¹ A/m².

In this example, current passing through the HM strip 202 2500 nm² cross-section area can be approximately 250 μA. The resistivity of Pt, the assumed material for the HD strip 202. is 10-7 ohm-m. The resistance R of this example HM strip 202, having the example cross-sectional area of 2500 nm² and length LT of 1 μm will therefore be R=40 ohms. Assuming, for purposes of example, a pulse width Δt being 1 ns, the energy dissipation per accumulation operation would be 2.5 fJ. Assuming a straintronic implementation of the voltage controlled conductance 106 portion of the multiplier 102, which can consume energy per multiplication that can be substantially smaller than 2.5 fJ, a total energy dissipated per multiply-and-accumulate (MAC) operation can be approximately 2.5 fJ. This is an illustration of the feature of small energy cost that can be provided, together with small footprint and non-volatility, by multiplier-accumulator devices and methods according to disclosed embodiments.

The amplitudes of the operand voltage pulses Vin1 and Vin2 are proportional to the two matrix elements a and b that are to be multiplied. The operand voltage pulses Vin can have a fixed width, Δt. The i-th current Iₒᵤₜ will be represented as (Iₒᵤₜ)ᵢ and has an amplitude that is proportional to a multiplication of value aᵢ by value bᵢ. With aᵢ encoded in the amplitude of the i-th pulse or Vᵢₙ₁ and bᵢ encoded in the amplitude of the i-th pulse of Vin2.

$${I}_{out} \approx - k ( {V}_{in 1} \times {V}_{in 2} ) ) \qquad Equation ( 4 )$$

The i-th current therefore has an amplitude (Iₒᵤₜ)ᵢ

$${( {I}_{out} )}_{i} ∝ {a}_{i} \times {b}_{i} \qquad Equation ( 5 )$$

The i-th current pulse can move the domain wall by an amount Δxi, in accordance with Equation (6)

$$Δ {x}_{i} = {v}_{i} Δ t \qquad Equation ( 6 )$$

where vi is the domain wall velocity imparted by the i-th current pulse. The domain wall velocity can be proportional to current density, over ranges of current density reasonably related to practices according to disclosed embodiments. Accordingly, the domain wall velocity can be proportional to the amplitude of the current pulse. Therefore, based on Equation (6), the movement amount Δxi can be represented by Equation (7):

$$Δ {x}_{i} ∝ {( {I}_{out} )}_{i} ∝ {a}_{i} \times {b}_{i} . \qquad Equation ( 7 )$$

As can be seen from Equation (7) in practices according to disclosed embodiments the domain wall moves after each pulse by an amount that proportional to the product of the two values ai and bi, i.e., to the product of the respective elements of the first matrix and the second matrix.

The example is described with perpendicular anisotropic layers This is an example configuration and is not intended as a limitations. In another one or more embodiments, the hard layer and soft layer can be in-plane anisotropic layers. The operation of domain movement and corresponding incremental, integrating movement of domain walls provided by such embodiments has some similarities and some differences.

### EXAMPLE 2

| Major axis dimension (L) | 800 | nm |
|---|---|---|
| Minor axis dimension (W) | 700 | nm |
| Thickness (d) | 2.2 | nm |
| Saturation magnetization (Ms) | 8.5 × 10⁵ | A/m |
| Dipole coupling field (Hd) | 1000 | Oe |
| Gilbert damping constant (symb) | 0.1 | |
| Saturation magnetization (sym) | 600 | ppm |
| Young's modulus | 120 | GPa |
| Piezoelectric coefficient (d33) | 1.5 × 10−9 | C/N |
| Piezoelectric layer thickness | 1 | μm |

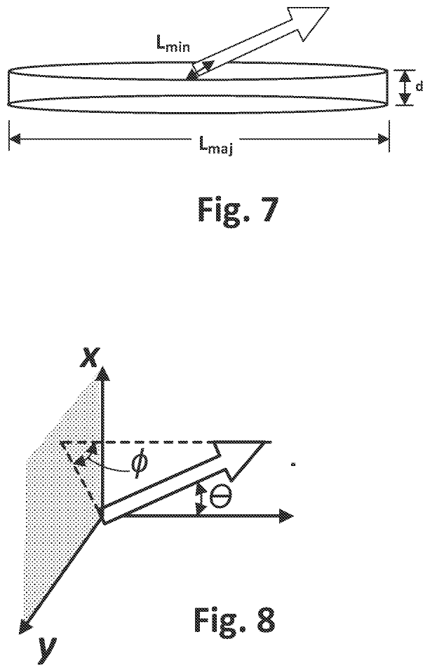

FIG. 7 shows an example geometry and certain dimension parameters of an elliptical soft layer of a straintronic MTJ.

FIG. 8 shows an example z-axis designation along the major, or easy axis of the soft layer and y-axis along the minor, or hard axis, an example pointing direction of the +z direction, and a corresponding polar angle. shows a plot of an example steady state angle between an example multiplier MTJ FM hard layer and FM soft layer as a function of gate voltage.

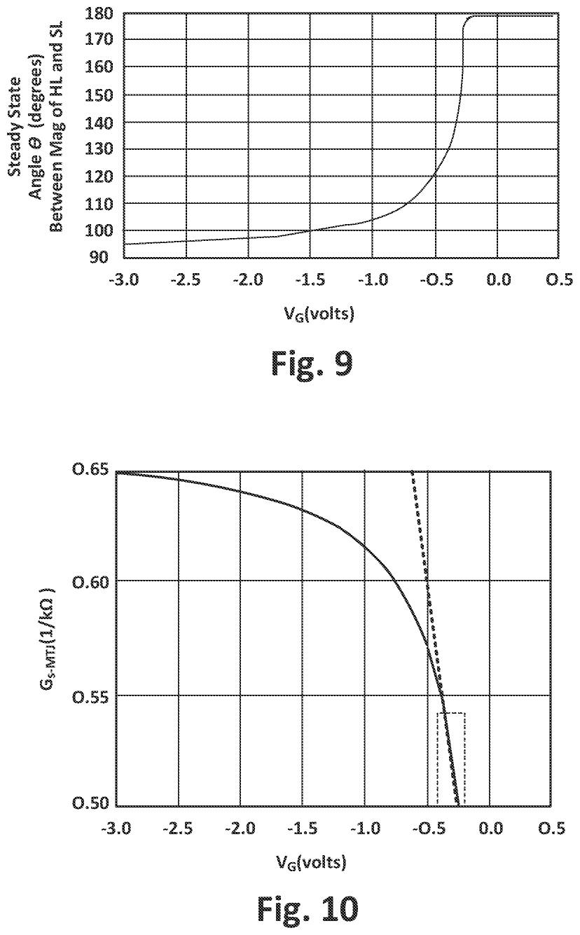

FIG. 9 shows a plot of an example steady state angle between an example multiplier MTJ FM hard layer and FM soft layer as a function of gate voltage.

FIG. 10 shows a plot of an example multiplier MTJ conductance versus gate voltage.

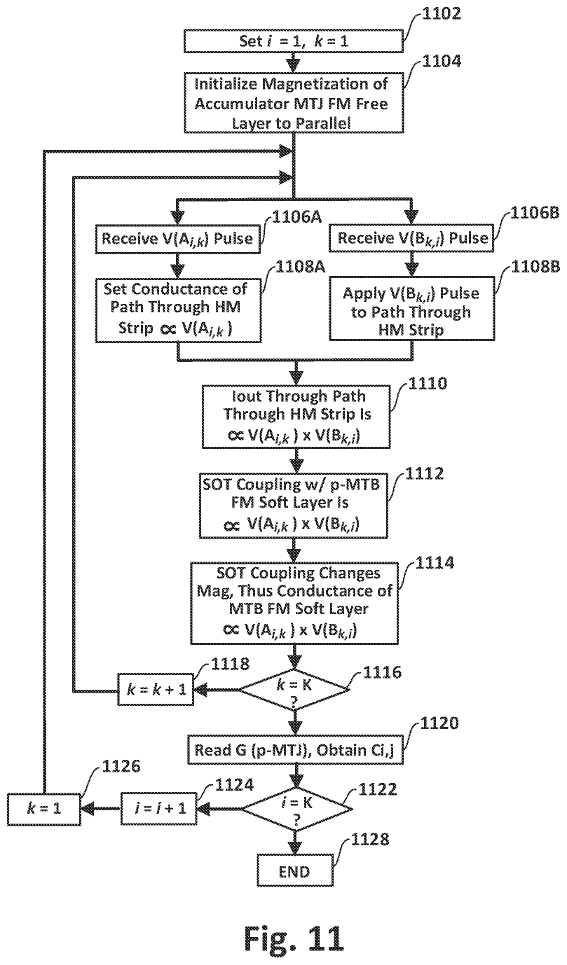

FIG. 11 shows a logic flow diagram of operations in an example matrix multiplication process provided on a non-volatile spin orbit torque coupled nanomagnetic magnetic tunnel junction based matrix multiplier according to one or more embodiments.

It is noted that, as used herein and in the appended claims, the singular forms “a,” “an,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. As will be apparent to those of skill in the art upon reading this disclosure, each of the individual embodiments described and illustrated herein has discrete components and features which may be separated from or combined with the features of any of the other several embodiments without departing from the scope or spirit of the present invention. Any recited method can be carried out in the recited order of events or in any other order which is logically possible. Where a range of values is provided, it is understood that each intervening value, to the tenth of the unit of the lower limit unless the context clearly dictates otherwise, between the upper and lower limit of that range and any other stated or intervening value in that stated range, is encompassed within the range. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention. While exemplary embodiments of the present invention have been disclosed herein, one skilled in the art will recognize, upon reading this disclosure in its entirety, that various changes and modifications may be made without departing from the scope as defined by the following claims.

What is claimed is:

1. A magnetic tunnel function (MTJ) based non-volatile non-binary matrix multiplier, comprising:
a multiplier comprising a straintronic magnetic tunnel junction (MTJ) configured with controllable strain induced changeable conductance based on a gate voltage and structure configured to generate, responsive to the gate voltage, strain in the straintronic MTJ's soft layer, wherein the straintronic MTJ is biased in the linear region of the straintronic MTJ conductance versus the gate voltage characteristic, and is configured to receive a multiplier and a multiplicand encoded in respective voltage pulses, and to apply the multiplier voltage pulses to the gate and the multiplicand voltage pulses across the across the straintronic MTJ, respectively, in a configuration that urges current pulses through the straintronic MTJ and a current path in series with the straintronic MTJ, amplitudes of the current pulses being proportional to a multiplication product of the multiplier voltage pulses and the and multiplicand voltage pulses;
an accumulator comprising a heavy metal (HM) strip integrated with an other MTJ and configured to receive the current pulses generated by the multiplier, in a flow configuration wherein the current pulses pass through the HM strip, in manner causing the HM strip to generate spin corresponding orbit torque (SOT) pulses, wherein the HM strip and the other MTJ are arranged in a mutual configuration wherein other MTJ includes a soft layer the SOT pulses move a domain wall in the soft layer of the other MTJ through distances that are proportional to the amplitudes of the current pulses and hence proportional to the product of the multiplier voltage and the multiplicand voltage.

2. The straintronic MTJ based non-volatile non-binary matrix multiplier of claim 1, further configured to receive a sequence of operand pairs, carrying a respective row of a first matrix and a respective column of a second matrix, each operand pair including a respective multiplier voltage pulse and a respective multiplicand voltage pulse, representing, respectively, an element of the row of the first matrix and an element of the column of the second matrix, wherein the HM metal strip and the soft layer of the other MTJ are mutually configured such that a total displacement of the domain wall, resulting from the sum of the movements produced by each of the current pulses, is proportional to the multiplication of the row of the first matrix with the column of the second matrix.

3. The straintronic MTJ based non-volatile non-binary matrix multiplier of claim 2, further comprising two resistors, respectively coupled to the straintronic MTJ in a configuration that diverts the current pulses through the two resistors, in a configuration such that one of the two resistors carries a portion of the current pulses, the portion being is proportional to the multiplication of the row of the first matrix with the column of the second matrix.

4. The straintronic MTJ based non-volatile matrix multiplier of claim 1, wherein:
the straintronic MTJ is supported on a piezoelectric substrate and comprises two gate electrodes that are mutually shorted, and are delineated on the piezoelectric substrate and configured to receive the voltage pulses encoding the multiplicand, and
the straintronic MTJ further comprises a terminal coupled via a resistive path to a connection, the connection being configured to receive the voltage pulses encoding the multiplicand from aa multiplicand pulsed voltage source encoding the multiplier, and
the resistive path comprises the heavy metal HM strip of the accumulator.

5. The straintronic MTJ based non-volatile matrix multiplier of claim 1, wherein the SOT generating HM strip is configured with a form geometry that includes a support surface, the MTJ is supported on the support surface, and the non-volatile multiplier-accumulator further comprises an insulating layer on the support surface and a metal layer positioned on the insulating layer, and the soft ferromagnetic layer includes a lower surface that electrically contacts and faces against the metal layer.

6. The straintronic MTJ based non-volatile matrix multiplier of claim 5, wherein the metal layer is a metal first layer, the FM hard layer comprises an upper surface facing opposite the lower surface of the FM soft layer, and the non-volatile multiplier-accumulator further comprises:
a metal second layer positioned on, facing against and in electrical contact with the upper surface of the FM hard layer,
a conductance first measurement terminal electrically coupled to the metal first layer; and
a second conductance second measurement terminal electrically coupled to the metal second layer.

7. The straintronic MTJ based non-volatile matrix multiplier of claim 1, wherein the soft layer is a ferromagnetic (FM) soft layer, and other MTJ further includes an FM hard layer, which is configured with a perpendicular anisotropy, and the straintronic MTJ based non-volatile matrix multiplier further comprises a magnetization initialization circuitry that is configured to set the magnetization state of the FM soft layer to a parallel magnetization, which is parallel to and aligned in the direction of the perpendicular anisotropy of the of the FM soft layer to the anisotropy.

8. The straintronic MTJ based non-volatile matrix multiplier of claim 7, wherein the magnetization initialization circuitry comprises an initialization current injection circuitry, configured to inject an initialization current through the HM strip, flowing in a direction opposite the flow direction of the current pulses Iout, having a magnitude effecting a reverse SOT coupling between the HM strip and the FM soft layer of the other MTJ, having a coupling magnitude effecting magnetization of the soft layer of the MTJ, having the magnetization direction of the FM hard layer.

9. The straintronic MTJ based non-volatile matrix multiplier of claim 8, wherein:
the SOT pulse is a SOT first pulse, the change in the non-volatile magnetization state is a first change, the multiplier voltage pulse is a multiplier first voltage pulse, the multiplicand voltage pulse is a multiplicand first voltage pulse, and
the multiplier is further configured to receive a multiplier second voltage pulse concurrent with a multiplicand second voltage pulse and, in response, output from the HM strip a second SOT coupling pulse proportional to a product of the multiplier second voltage and the multiplicand voltage and configured to deterministically effectuate a second change in the non-volatile magnetization state proportional to the second SOT coupling pulse.

10. A method for performing non-volatile multiplication of matrices, using two a magnetic tunnel junctions (MTJ), comprising:
receiving a sequence of K operand pairs, each comprising a respective multiplier voltage value carried by a multiplier voltage pulse and a multiplicand voltage value carried by a multiplicand voltage pulse and, in response, performing a corresponding K incremental displacement of the domain wall in the soft layer of the accumulator MTJ, obtaining an end displacement that is proportional to the multiplication of one row of one matrix with one column of another;
detecting a resistance of the accumulator MTJ corresponding to the end magnetization state; and
determining, based at least in part on the resistance corresponding to the end magnetization state, a sum of K multiplication products, each of the K multiplication products being a multiplication product of the multiplier voltage value and the multiplicand voltage value of a respective one of the K multiplication operand pairs.

11. The method of claim 11 for performing non-volatile multiplication of matrices, further comprising: preceding a commencement of performing the K deterministic changes to the non-volatile magnetization state of the soft ferromagnetic (FM) layer, initializing the non-volatile state to an initial non-volatile magnetization state.

12. The method of claim 11 for performing non-volatile multiplication of matrices, wherein:
the sequence of K operand pairs is a first sequence of K operand pairs, each pair including an A_{i,k} element and a B_{k,i} element, the A_{i,k} element being a k-th column element of a K-column of an i-th row of the first matrix and the B_{k,i} element being a k-th row element of a K-row i-th column of the second matrix.

13. A non-volatile magnetic-tunnel junction (MTJ) based matrix multiplier, comprising:
an MTJ, a soft ferromagnetic layer and a hard ferromagnetic layer, the hard ferromagnetic layer being anisotropic in a reference alignment;
means for setting a magnetization state of the soft ferromagnetic layer to a reset magnetization state; and
means for receiving a pulse of a first operand voltage and a pulse of a second operand voltage and, in response, changing the magnetization state of the soft layer by an amount, the amount being proportional to a multiplication product of the first operand voltage and the second operand voltage.

14. The non-volatile MTJ based matrix multiplier of claim 13, wherein the means for receiving the first operand voltage pulse and the second operand voltage pulse and, in response, changing the magnetization state of the soft layer by the amount, is configured for receiving another first operand voltage pulse and another second operand voltage pulse and, in response, further changing the magnetization state of the soft layer by another amount, the another amount being proportional to a multiplication product of the another first operand voltage and the another second operand voltage.
